(19) United States
(12) Patent Application Publication
(10) Pub. No.: US 2023/0197561 A1
(43) Pub. Date: Jun. 22, 2023

(54) POWER SEMICONDUCTOR MODULE COMPRISING A SUBSTRATE, POWER SEMICONDUCTOR COMPONENTS AND COMPRISING A PRESSURE BODY

(71) Applicant: SEMIKRON ELEKTRONIK GMBH & CO. KG, NUREMBERG (DE)

(72) Inventors: Jörg AMMON, Flein (DE); Harald KOBOLLA, Seukendorf (DE); Ralf EHLER, Markt Erlbach (DE); Simon HÜTTMEIER, Haundorf (DE)

(73) Assignee: SEMIKRON ELEKTRONIK GMBH & CO. KG, NUREMBERG (DE)

(21) Appl. No.: 18/078,854

(22) Filed: Dec. 9, 2022

(30) Foreign Application Priority Data
Dec. 21, 2021 (DE) 10 2021 134 001.2

(51) Int. Cl. H01L 23/40; H01L 23/367; H01L 25/065; H01L 23/04; H01L 23/00

(52) U.S. Cl. CPC H01L 23/4006; H01L 23/3672; H01L 25/0655; H01L 23/04; H01L 24/48; H01L 24/45; H01L 2023/4081; H01L 2224/48225; H01L 2224/45147

(57) ABSTRACT

A power semiconductor module has a substrate and an insulation layer and a metal layer arranged on the insulation layer, forming conductor tracks, comprising power semiconductor components arranged on the metal layer and conductively contacted with the metal layer. A pressure device arranged above the substrate in the normal direction of the insulation layer and having a pressure body and pressure elements running toward the substrate. The pressure elements each being connected to the pressure body to move resiliently in the normal direction via a spring element. The pressure body exerting a pressure onto the pressure elements in the direction toward the substrate via the spring elements, the pressure elements being arranged in such a way that, owing to the pressure exerted by the pressure body, they press onto power semiconductor component surrounding regions, surrounding the power semiconductor components, of the substrate.

### CROSS REFERENCE TO RELATED APPLICATIONS

This application relates to and claims priority to DE 10 2021 134 001.2 filed Dec. 21, 2021, the entire contents of which are incorporated herein fully by reference.

### BACKGROUND OF THE INVENTION

### Field of the Invention

The invention relates to a power semiconductor module comprising a substrate, power semiconductor components, comprising a pressure body and comprising spring elements.

### Description of the Related Art

DE 10 2017 125 052 A1 discloses a power semiconductor module comprising a substrate, comprising power semiconductor components arranged on the substrate, comprising a foil stack electrically conductively connected to the power semiconductor components and to conductor tracks of the substrate with suitable circuitry, comprising a pressure body and comprising spring elements. The spring elements exert a pressure onto a surface, averted from the substrate, of the respective power semiconductor component in the direction toward the substrate via the foil stack. When the power semiconductor module, by way of its substrate, is arranged on a cooling device, the regions, arranged beneath the power semiconductor components in alignment with the power semiconductor components, of the substrate are pressed against the cooling device as a result, so that these regions and therefore the power semiconductor components that heat up during operation of the power semiconductor module are thermally particularly well coupled to the cooling device and therefore cooled particularly well by the cooling device. One disadvantage of this is that, in order to form such a power semiconductor module in which the power semiconductor components can be cooled very efficiently by a cooling device, it is necessary on a practical level to use a foil stack for electrically connecting the power semiconductor: components with suitable circuitry since no pressure should be exerted onto the bonding wires otherwise routinely used in the art or onto the bonding wire connections otherwise routinely arranged on the top side of the power semiconductor component in the art for electrically connecting the power semiconductor components with suitable circuitry since said pressure can have a negative effect on the service life of the bonding wire connections.

### ASPECTS AND OBJECTS OF THE INVENTION

The invention is based on the object of providing a power semiconductor module, the power semiconductor components of which can be thermally well coupled to a cooling device, so that the power semiconductor components are efficiently cooled by the cooling device.

According to the invention, this object is achieved by a power semiconductor module comprising a substrate which has an electrically nonconductive insulation layer and a metal layer arranged on the insulation layer and structured to form conductor tracks, comprising power semiconductor components arranged on the metal layer and electrically conductively contacted with the metal layer, comprising a pressure device arranged above the substrate in the normal direction of the insulation layer and having a pressure body and pressure elements running toward the substrate, the pressure elements each being connected to the pressure body so as to move resiliently in the normal direction of the insulation layer via a spring element, associated with the respective pressure element, of the pressure device, the pressure body being designed to exert a pressure onto the pressure elements in the direction toward the substrate via the spring elements, the pressure elements being arranged in such a way that, owing to the pressure exerted by the pressure body, they press onto power semiconductor component surrounding regions, surrounding the power semiconductor components, of the substrate.

It proves to be advantageous when the pressure elements are arranged in such a way that, owing to the pressure exerted by the pressure body, they press onto the substrate directly next to the power semiconductor components. As a result, the power semiconductor components, when the power semiconductor module, by way of its substrate, is arranged on a cooling device, are thermally particularly well coupled to the cooling device and therefore can be particularly efficiently cooled by the cooling device.

It further proves to be advantageous when the pressure elements are of electrically nonconductive design. As a result, the power semiconductor module has a high dielectric strength.

It furthermore proves to be advantageous when the spring elements are designed as layer regions of an elastic layer arranged between the pressure piece and the pressure elements. As a result, the spring elements can be produced in a particularly efficient manner.

In this context, it proves to be advantageous when the elastic layer is designed in a manner structured to form the layer regions or is of one-piece design. When the elastic layer is designed in a manner structured to form the layer regions, the spring elements are then designed in a manner clearly separated from one another, so that precise positioning of the pressure elements on the spring elements is made easier. When the elastic layer is of one-piece design, the elastic layer is then of particularly simple design.

Furthermore, it proves to be advantageous when the pressure elements are connected to the layer regions in a materially bonded manner, in particular by means of an adhesive connection. As a result, the pressure elements are connected to the layer regions in a particularly reliable manner.

It further proves to be advantageous when the pressure elements are connected to one another via webs designed so as to be flexible in the normal direction of the insulation layer. As a result, efficient fitting of the pressure elements is possible during production of the power semiconductor module.

In this context, it proves to be advantageous when the frame element is connected to the pressure body, in particular by means of at least one interlocking connection, each of which is designed as a snap-action connection in particular. As a result, particularly efficient fitting of the pressure elements is possible during production of the power semiconductor module.

It furthermore proves to be advantageous when the respective pressure element has a pressure introducing portion at its end region facing the respective spring element, the pressure introducing portion having a planar surface region facing the spring element and running perpendicularly to the normal direction of the insulation layer or having a concavely running surface region facing the spring element. As a result, the pressure can be transmitted particularly well from the spring elements to the pressure elements.

It furthermore proves to be advantageous when the pressure body is designed in one piece together with the spring elements and with the pressure elements. As a result, the pressure device can be produced in a particularly efficient manner.

In this context, it proves to be advantageous when at least one of the spring elements is formed by means of at least one slot made in the pressure body and/or when at least one of the spring elements has a curved profile, in particular an S-shaped profile. As a result, the spring elements can be produced in a particularly efficient manner.

It further proves to be advantageous when the respective pressure element has a foot portion running in the normal direction of the insulation layer toward the substrate, wherein the foot portion has a rectangular, L-shaped, arcuate, circular or square cross section. As a result, the geometric shape of the respective pressure element can be individually adapted to the spatial arrangement of the power semiconductor components arranged on the substrate.

It further proves to be advantageous when the power semiconductor components are electrically conductively connected to the conductor tracks of the structured metal layer by means of bonding wires of the power semiconductor module, the bonding wires being formed, in particular, from copper or from a copper alloy, the power semiconductor components, for being contacted with the bonding wires, each having a metallization metal layer, in particular designed as a nickel metal layer, the respective bonding wire being electrically conductively contacted with the respective metallization metal layer, in particular by means of an ultrasonic welding connection.

It furthermore proves to be advantageous when the power semiconductor module has a pressure generating device which is designed to generate a pressure acting on the pressure body in the direction of the substrate. As a result, the power semiconductor module itself has a pressure generating device.

In this context, it proves to be advantageous when the pressure generating device transmits the pressure generated by it onto the pressure body via at least one spring, arranged between the pressure generating device and the pressure body, of the power semiconductor module. As a result, the level of the pressure acting on the pressure body is limited.

It furthermore proves to be advantageous when the pressure body is a constituent part of a first housing element of the power semiconductor module. As a result, the power semiconductor module is of particularly compact design.

In this context, it proves to be advantageous when the power semiconductor module has a second housing element encircling the substrate and connected to the substrate, the first housing element being connected to the second housing element by means of an interlocking connection, which is designed as a snap-action connection in particular, in such a way that the pressure body, when the first housing element is in a first position in relation to the second housing element, does not exert any pressure or exerts only a slight pressure onto the pressure elements in the direction toward the substrate via the spring elements, the interlocking connection being designed in such a way that the first housing element, starting from the first position of the first housing element, can be moved to a second position in the normal direction of the insulation layer toward the substrate, the pressure body, when the first housing element is in the second position in relation to the second housing element and when the pressure body does not exert any pressure onto the pressure elements in the direction toward the substrate via the spring elements in the first position, exerting a pressure onto the pressure elements in the direction toward the substrate via the spring elements, or the pressure body, when the pressure body exerts only a slight pressure onto the pressure elements in the direction toward the substrate via the spring elements in the first position, exerting a higher pressure than in the first position onto the pressure elements in the direction toward the substrate via the spring elements. As a result, particularly efficient production and fitting of the power semiconductor module is rendered possible.

It further proves to be advantageous that, when the power semiconductor module has a pressure generating device which is designed to generate a pressure acting on the pressure body in the direction of the substrate, the pressure generating device is designed as a fastening means which is designed to fasten the power semiconductor module on a cooling device. As a result, particularly efficient fitting of the power semiconductor module on a cooling device is rendered possible.

In this context, it proves to be advantageous when the cooling device is designed as a base plate which is intended to be fitted to a heat sink or is de signed as a heat sink.

Furthermore, a power semiconductor device comprising a power semiconductor module according to the invention and comprising a cooling device, wherein the pressure body exerts pressure onto the pressure elements in the direction toward the substrate via the spring elements, so that the substrate is pressed against the cooling device, proves to be advantageous.

It should be noted that the elements mentioned in the singular may be present multiply.

The above and other aspects, features, objects, and advantages of the present invention will become apparent from the following description read in conjunction with the accompanying drawings, in which like reference numerals designate the same elements.

### BRIEF DESCRIPTION OF THE DRAWINGS

FIG. 1 shows a sectional view of a design of a power semiconductor device comprising a design of a power semiconductor module according to the invention and comprising a cooling device.

FIG. 2 shows a view of a power semiconductor component arranged on a structured metal layer or on a conductor track of a substrate and of pressure elements of a power semiconductor module according to the invention.

FIG. 3 shows a plan view of a frame element, of pressure elements and of webs of a power semiconductor module according to the invention.

FIG. 4 shows a sectional view of a design of a pressure element of a power semiconductor module according to the invention.

FIG. 5 shows a perspective view of a design of a pressure device of a power semiconductor module according to the invention.

FIG. 6 shows a perspective sectional view of the pressure device according to FIG. 5.

FIG. 7 shows a perspective view of a further design of a pressure device of a power semiconductor module according to the invention.

FIG. 8 shows a perspective sectional view of the pressure device according to FIG. 7.

FIG. 9 shows sectional views of a plurality of designs of foot portions of pressure elements of a power semiconductor module according to the invention.

FIG. 10 shows a sectional view of a further design of a power semiconductor device comprising a further design of a power semiconductor module according to the invention and comprising a cooling device.

### DETAILED DESCRIPTION OF THE PREFERRED EMBODIMENTS

Reference will now be made in detail to embodiments of the invention. Wherever possible, same or similar reference numerals are used in the drawings and the description to refer to the same or like parts or steps. The drawings are in simplified form and are not to precise scale. The word ‘couple’ and similar terms do not necessarily denote direct and immediate connections, but also include connections through intermediate elements or devices. For purposes of convenience and clarity only, directional (up/down etc.) or motional (forward/back, etc.) terms may be used with respect to the drawings. These and similar directional terms should not be construed to limit the scope in any manner. It will also be understood that other embodiments may be utilized without departing from the scope of the present invention, and that the detailed description is not to be taken in a limiting sense, and that elements may be differently positioned, or otherwise noted as in the appended claims without requirements of the written description being required thereto.

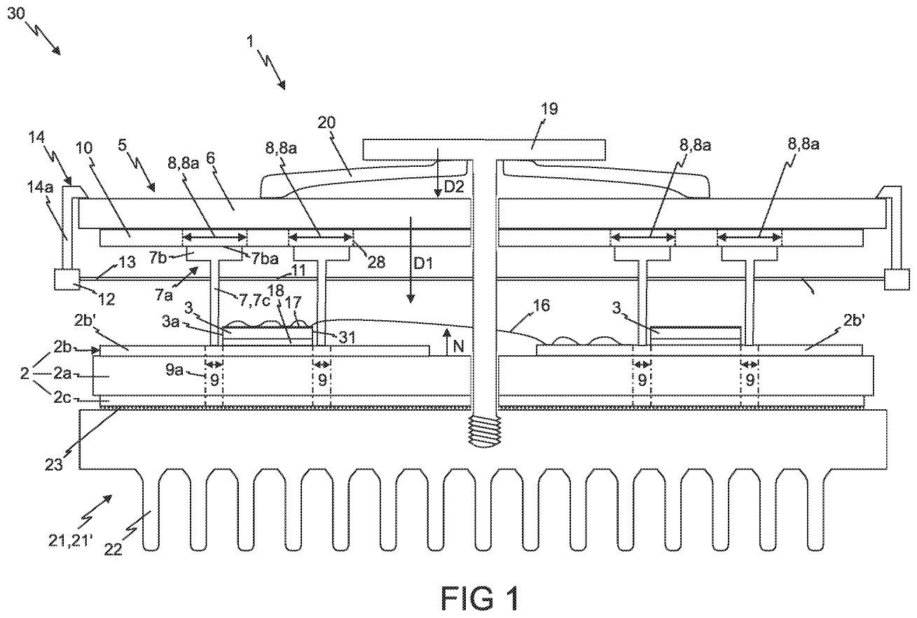

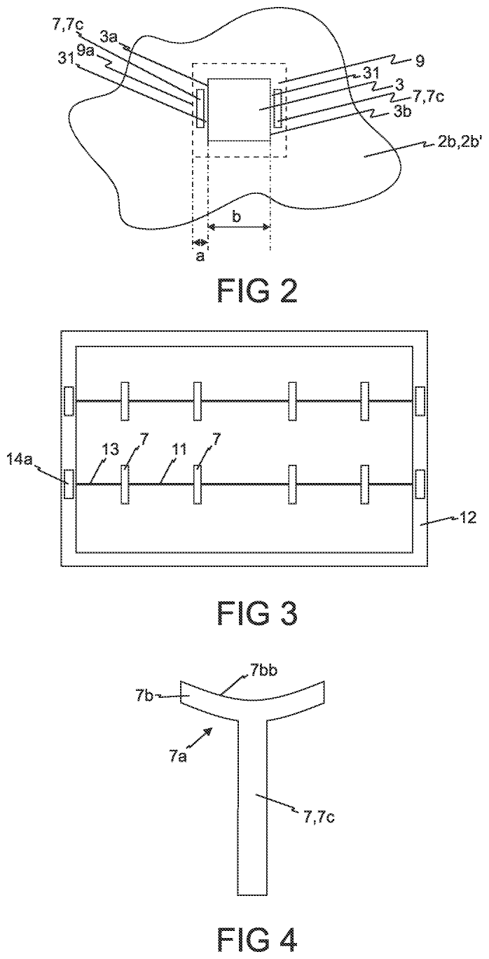

FIG. 1 illustrates a power semiconductor device 30 comprising a power semiconductor module 1 according to the invention and comprising a cooling device 21. FIG. 2 illustrates a power semiconductor component 3 arranged on a metal layer 2b or on a conductor track 2b′ of a substrate 2 and pressure elements 7 of a power semiconductor module 1 according to the invention.

The power semiconductor module 1 according to the invention has a substrate 2 which has an electrically nonconductive insulation layer 2a and a metal layer 2b arranged on the insulation layer 2a and structured to form conductor tracks 2b′.

The substrate 2 preferably has a, preferably unstructured, further metal layer 2c, the insulation layer 2a being arranged between the metal layer 2b and the further metal layer 2c. The insulation layer 2a can be designed, for example, as a ceramic plate. The respective substrate 2 can be designed, for example, as a direct copper bonded substrate (DCB substrate), as an active metal brazing substrate (AMB substrate), as a substrate consisting of a composite material, composed of epoxy resin and glass-fiber fabric, such as FR4 or as an insulated metal substrate (IMS).

The power semiconductor module 1 furthermore has power semiconductor components 3 arranged on the metal layer 2b, expressed more precisely on the conductor tracks 2b′, and electrically conductively contacted with the metal layer 2b, expressed more precisely with the conductor tracks 2b′. Here, the power semiconductor components 3 are preferably electrically conductively contacted with the structured metal layer 2b by means of a soldered or sintered layer 18 arranged between the structured metal layer 2b and the power semiconductor components 3. The respective power semiconductor component 3 is present in general in the form of a power semiconductor switch or a diode. Here, the power semiconductor switches are present in general in the form of transistors, such as IGBTs (insulated gate bipolar transistors) or MOSFETs (metal oxide semiconductor field effect transistors) for example, or in the form of thyristors.

The power semiconductor module 1 furthermore has a pressure device 5 arranged above the substrate 2 in the normal direction N of the insulation layer 2a and having a pressure body 6 and pressure elements 7 running toward the substrate 2. The pressure elements 7 are preferably of electrically nonconductive design. The pressure body 6 can be formed from metal or from a plastic. The pressure elements 7 are preferably formed from plastic.

The pressure elements 7 are each connected to the pressure body 6 so as to move resiliently in the normal direction N of the insulation layer 2a via a spring element 8, associated with the respective pressure element 7, of the pressure device 5.

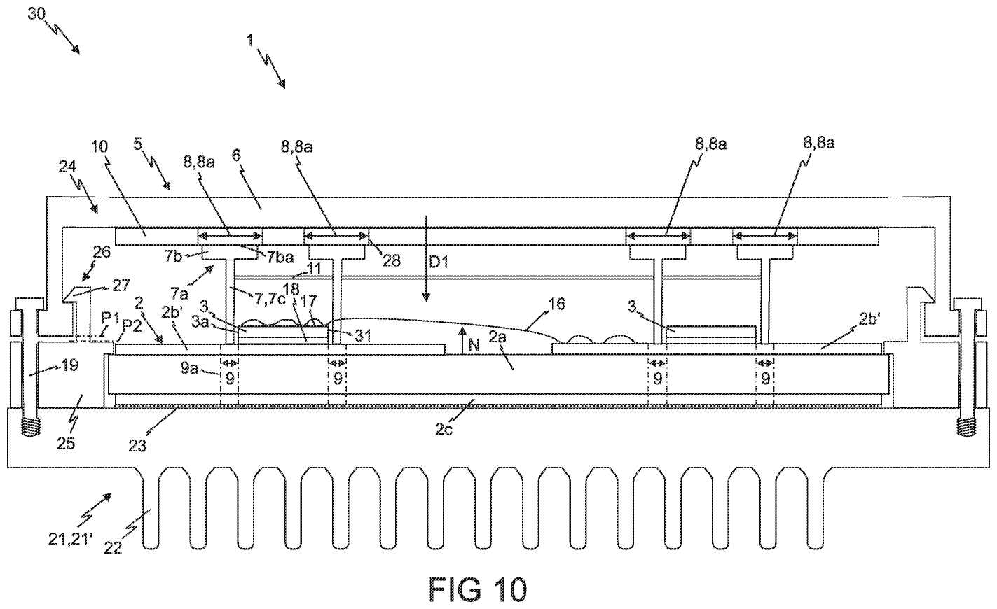

Within the scope of the exemplary embodiment according to FIG. 1, the spring elements 8 are designed as layer regions 8a of an elastic layer 10 arranged between the pressure body 6 and the pressure elements 7. The elastic layer 10 can be designed in a structured manner to form the layer regions 8a, so that, for example, the layer regions 8a are arranged in a manner completely separated from one another by trenches arranged between the layer regions 8a or are of one-piece design as in the exemplary embodiment according to FIG. 1, so that virtually separated active regions of the elastic layer 10 in the form of layer regions 8a are associated with the pressure elements 7. In FIG. 1, the virtual ends 28 of the layer regions 8a are illustrated using dashed lines. The elastic layer 10 can be formed, for example, from an elastomer. The elastomer is preferably designed as silicone. The silicone is preferably present in the form of a crosslinked liquid silicone rubber or in the form of a crosslinked solid silicone rubber. The elastic layer 10 is preferably connected to the pressure body 6 in a materially bonded manner, in particular by means of an adhesive connection, this not being illustrated in FIG. 1 and FIG. 10 for reasons of clarity.

The pressure elements 7 can be connected to the spring elements 8, here to the layer regions 8a, in a materially bonded manner, in particular by means of an adhesive connection.

The respective pressure element 7 preferably has a pressure introducing portion 7b at its end region 7a facing the respective spring element 8, the pressure introducing portion 7b having a planar surface region 7ba (see FIG. 1 and FIG. 10) facing the spring element 8 and running perpendicularly to the normal direction N of the insulation layer 2a or, as illustrated by way of example in FIG. 4, having a concavely running surface region 7bb facing the spring element 8.

The pressure elements 7 are preferably connected to one another via webs 11 designed so as to be flexible in the normal direction N of the insulation layer 2a.

The power semiconductor module 1 furthermore preferably has a frame element 12, the pressure elements 7 being connected to the frame element 12 via further flexible webs 13. The frame element 12 is preferably connected to the pressure body 6, in particular by means of at least one interlocking connection 14, each of which is designed as a snap-action connection in particular. In order to realize the respective snap-action connection 14, the frame element 12 preferably has a respective snap-action hook 14a which is connected to the pressure body 6 in an interlocking manner.

The pressure body 6 is designed to exert a pressure D1 onto the pressure elements 7 in the direction toward the substrate 2 via the spring elements 8. The pressure elements 7 are arranged in such a way that, owing to the pressure D1 exerted by the pressure body 6, they press onto power semiconductor component surrounding regions 9, surrounding the power semiconductor components 3, of the substrate 2. The pressure elements 7 are preferably in mechanical contact with the power semiconductor component surrounding regions 9 of the substrate 2. The pressure elements 7 can be connected to the substrate 2 by means of an adhesive connection.

When the power semiconductor module 1 according to the invention, by way of its substrate 2, is arranged on a cooling device 21, the regions, arranged beneath the power semiconductor components 3 in alignment with the power semiconductor components 3, of the substrate 2 are pressed against the cooling device 21 as a result since the pressure elements 7 press onto power semiconductor component surrounding regions 9, surrounding the power semiconductor components 3 in the direction toward the substrate 2, so that these regions and therefore the power semiconductor components 3 that heat up during operation of the power semiconductor module 1 are thermally particularly well coupled to the cooling device 21 and therefore cooled particularly efficiently by the cooling device 21. Since during this introduction of pressure onto the substrate, when using bonding wires, no pressure is exerted onto the bonding wire connections arranged on the top side of the power semiconductor components, bonding wire connections for electrically connecting the power semiconductor components with suitable circuitry can be used during this introduction of pressure since no pressure, which can have a negative effect on the service life of the bonding wire connections, is exerted onto the bonding wire connections. On account of a respective spring element 8 being associated with a respective pressure element 7, for example, different degrees of thermal expansion of the pressure elements 7 can be individually compensated for by means of the spring elements 8 due to different heating of the pressure elements 7 occurring during operation of the power semiconductor module 1.

As illustrated by way of example in FIG. 1 and FIG. 2 and FIG. 10, the respective power semiconductor component surrounding region 9, starting from a boundary edge 3a of the power semiconductor component 3, extends in the perpendicular direction with respect to the normal direction N of the insulation layer 2a as far as the outer border 9a of the power semiconductor component surrounding region 9. The distance a between the boundary edge 3a of the power semiconductor component 3 and the outer border 9a of the power semiconductor component surrounding region 9 is preferably less than 100%, in particular preferably less than 60%, in particular preferably less than 30%, of the distance b between the boundary edge 3a of the power semiconductor component 3 and the further boundary edge 3b, situated opposite the boundary edge 3a of the power semiconductor component 3, of the power semiconductor component 3 (see FIG. 2).

The pressure elements 7 are preferably arranged in such a way that, owing to the pressure D1 exerted by the pressure body 6, they press onto the substrate 2 directly next to the power semiconductor components 3. In this case, there can be a gap 31 between the pressure elements 7 and the power semiconductor components 3 in each case.

As illustrated by way of example in FIG. 1 and FIG. 2 and FIG. 10, at least two pressure elements 7 are preferably associated with the respective power semiconductor component 3, these at least two pressure elements 7 being arranged in such a way that they press against two mutually opposite sides of the power semiconductor component 3 onto the power semiconductor component surrounding region 9, associated with the power semiconductor component 3 in question, of the substrate 2.

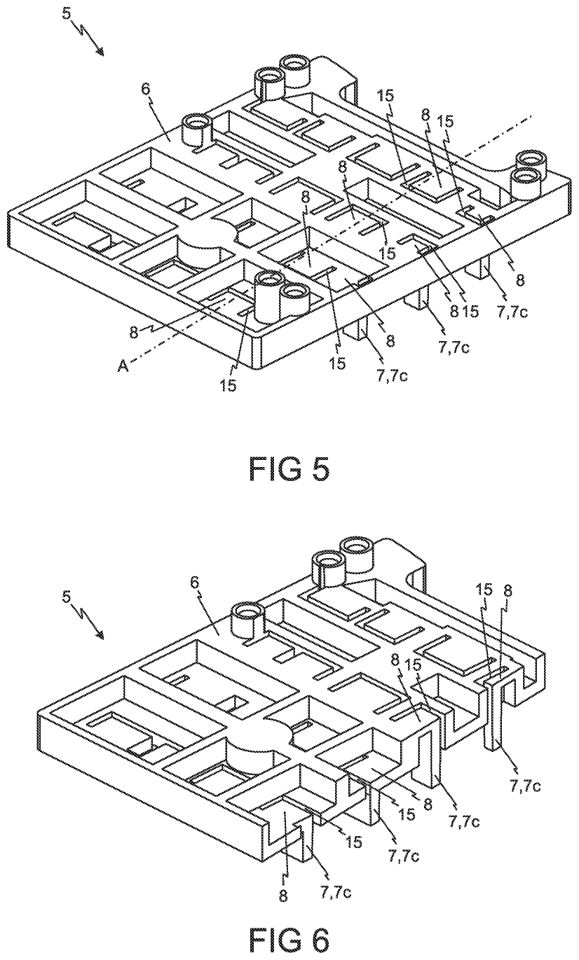

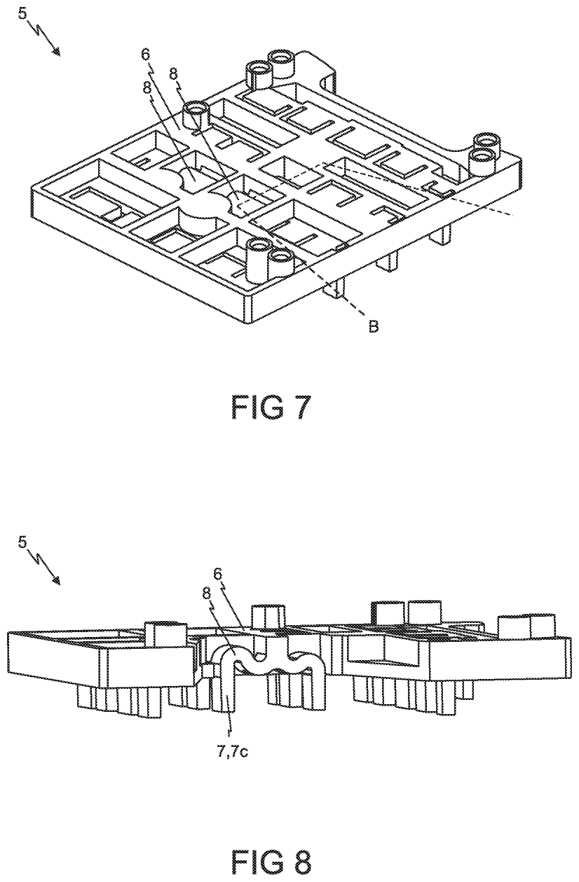

As illustrated by way of example in FIGS. 5 to 8, the pressure body 6 can be designed in one piece together with the spring elements 8 and with the pressure elements 7. FIG. 5 and FIG. 6 illustrate, by way of example, a pressure device 5 of one-piece design, in which the spring elements 8 are each formed by means of at least one slot 15 made in the pressure body 6. As an alternative, the spring elements 8 can also have a curved profile, in particular an S-shaped profile. As illustrated by way of example in FIG. 7 and FIG. 8, some of the spring elements 8 can each be formed by means of at least one slot 15 made in the pressure body 6 and some others of the spring elements 8 can have a curved profile, in particular an S-shaped profile. More generally, at least one of the spring elements 8 can be formed by means of at least one slot 15 made in the pressure body 6 and/or at least one of the spring elements 8 can have a curved profile, in particular an S-shaped profile. The respective pressure device 5 according to FIG. 5, FIG. 6, FIG. 7 and FIG. 8 can be formed, for example, from a plastic or a metal body encapsulated with plastic by injection molding and in which, for example, the frame 6 and the pressure pieces 7 consist of plastic and the spring elements 8 consist of a metal.

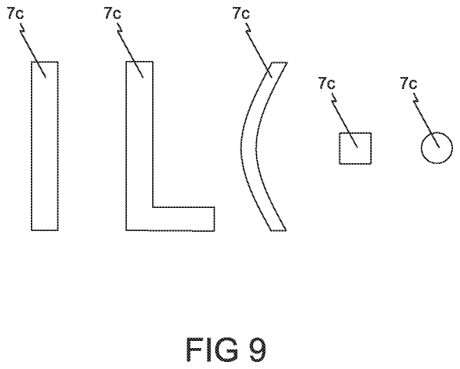

The respective pressure element 7 preferably has a foot portion 7c running in the normal direction N of the insulation layer 2a toward the substrate 2, the foot portion 7c, as illustrated by way of example in FIG. 9, preferably having a rectangular, L-shaped, arcuate, circular or square cross section.

The power semiconductor components 3 are preferably electrically conductively connected to the conductor tracks 2b′ of the structured metal layer 2b by means of bonding wires 16 of the power semiconductor module 1. The bonding wires 16 are preferably formed from copper or from a copper alloy, the power semiconductor components 3, for being contacted with the bonding wires 16, preferably each having a metallization metal layer 17, in particular designed as a nickel metal layer. The respective bonding wire 16 is preferably electrically conductively contacted with the respective metallization metal layer 17, in particular by means of an ultrasonic welding connection.

The power semiconductor module 1 preferably has a pressure generating device 19, here a screw, which is designed to generate a pressure D2 acting on the pressure body 6 in the direction of the substrate 2. The pressure generating device 19 preferably transmits the pressure D2 generated by it onto the pressure body 6 via at least one spring 20, arranged between the pressure generating device 19 and the pressure body 6, of the power semiconductor module 1.

FIG. 10 illustrates a sectional view of a further design of a power semiconductor device 30 comprising a further design of a power semiconductor module 1 according to the invention and comprising a cooling device 21. In the power semiconductor module 1 according to the invention as per FIG. 10, the pressure body 6 is a constituent part of a first housing element 24 of the power semiconductor module 1.

The power semiconductor module 1 according to FIG. 10 has a second housing element 25 encircling the substrate 2 and connected to the substrate 2. The first housing element 24 is connected to the second housing element 25 by means of an interlocking connection 26, which is designed as a snap-action connection 26 in particular, in such a way that the pressure body 6, when the first housing element 24 is in a first position P1 in relation to the second housing element 25, does not exert any pressure D1 or exerts only a slight pressure D1 onto the pressure elements 7 in the direction toward the substrate 2 via the spring elements 8. The interlocking connection 26 is designed in such a way that the first housing element 24, starting from the first position P1 of the first housing element 24, can be moved to a second position P2 in the normal direction N of the insulation layer 2a toward the substrate 2, the pressure body 6, when the first housing element 24 is in the second position P2 in relation to the second housing element 25 and when the pressure body 6 does not exert any pressure D1 onto the pressure elements 7 in the direction toward the substrate 2 via the spring elements 8 in the first position, exerting a pressure D1 onto the pressure elements 7 in the direction toward the substrate 2 via the spring elements 8, or the pressure body 6, when the pressure body 6 exerts only a slight pressure D1 onto the pressure elements 7 in the direction toward the substrate 2 via the spring elements 8 in the first position, exerting a higher pressure D1 than in the first position P1 onto the pressure elements 7 in the direction toward the substrate 2 via the spring elements 8.

When the power semiconductor module 1, by way of its substrate 2, is arranged on a cooling device 21, the pressure elements 7, when the first housing element 24 is in the second position P2 in relation to the second housing element 25, are pressed with corresponding pressure onto power semiconductor component surrounding regions 9, surrounding the power semiconductor components 3, of the substrate 2 in the direction of the substrate 2, so that these regions and therefore the power semiconductor components 3 that heat up during operation of the power semiconductor module 1, are thermally very well coupled to the cooling device 21 and therefore cooled particularly efficiently by the cooling device 21.

The pressure generating device 19 is, as illustrated by way of example in FIG. 1 and FIG. 10, designed as a fastening means 19, in particular as a screw 19, the fastening means 19 being designed to fasten the power semiconductor module 1 on a cooling device 21.

In the design of the power semiconductor module 1 according to FIG. 1, the pressure device 5 and the substrate 2 preferably each have a passage opening through which the fastening means 19, here the screw 19, runs. In the design of the power semiconductor module 1 according to FIG. 10, the first and the second housing element 24 and 25 preferably each have a passage opening through which the fastening means 19, here the screw 19, runs.

The cooling device 21 can be designed as a base plate which is intended to be fitted to a heat sink or, as illustrated by way of example in FIG. 1 and FIG. 10, can be designed as a heat sink 21′. The heat sink 21 has cooling fins and/or cooling pins 22. The heat sink 21 preferably has a hole provided with an internal thread, the screw 19 being screwed into said hole.

For external electrical connection, the power semiconductor module 1 has load and preferably auxiliary connection elements, which are not illustrated in FIG. 1 and FIG. 10 for reasons of clarity. The load connection elements are preferably electrically conductively contacted with the structured metal layer 2b, for example by means of a soldered, sintered or welded connection.

The power semiconductor device 30 has a power semiconductor module 1 according to the invention and the cooling device 21, the pressure body 6 exerting pressure onto the pressure elements 7 in the direction toward the substrate 2 via the spring elements 8, so that the substrate 2 is pressed against the cooling device 21.

A thermally conductive layer 23, which can consist of a thermally conductive paste for example, can be arranged between the substrate 2 and the cooling device 21.

Also, the inventors intend that only those claims which use the specific and exact phrase “means for” are intended to be interpreted under 35 USC 112. The structure herein is noted and well supported in the entire disclosure. Moreover, no limitations from the specification are intended to be read into any claims, unless those limitations are expressly included in the claims.

Having described at least one of the preferred embodiments of the present invention with reference to the accompanying drawings, it will be apparent to those skills that the invention is not limited to those precise embodiments, and that various modifications and variations can be made in the presently disclosed system without departing from the scope or spirit of the invention. Thus, it is intended that the present disclosure cover modifications and variations of this disclosure provided they come within the scope of the appended claims and their equivalents.

What is claimed is:

1. A power semiconductor module (1), comprising:
a substrate (2) which has an electrically nonconductive insulation layer (2a) and a metal layer (2b) arranged on the insulation layer (2a) and structured to form conductor tracks (2b′);
a plurality of power semiconductor components (3) arranged on the metal layer (2b) and electrically conductively contacted with the metal layer (2b);
a pressure device (5) arranged above the substrate (2) in the normal direction (N) of the insulation layer (2a) and having a pressure body (6) and a plurality of pressure elements (7) running toward the substrate (2);
the pressure elements (7) each being connected to the pressure body (6) so as to move resiliently in the normal direction (N) of the insulation layer (2a) via a spring element (8), associated with the respective pressure element (7), of the pressure device (5);
the pressure body (6) being designed to exert a pressure (D1) onto the pressure elements (7) in the direction toward the substrate (2) via the spring elements (8);
the pressure elements (7) arranged in such a way that, owing to the pressure (D1) exerted by the pressure body (6), the pressure elements (7) press onto respective power semiconductor component surrounding regions (9), proximate respective ones of the power semiconductor components (3), of the substrate (2).

2. The power semiconductor module (1), as claimed in claim 1, wherein:
the pressure elements (7) are arranged such that, owing to the pressure (D1) exerted by the pressure body (6), the pressure elements (7) press onto the substrate (2) directly next to the power semiconductor components (9).

3. The power semiconductor module (1), as claimed in claim 2, wherein:
the pressure elements (7) are electrically nonconductive.

4. The power semiconductor module (1), as claimed in claim 3, wherein:
the spring elements (8) are designed as layer regions (8a) of an elastic layer (10) arranged between the pressure body (6) and the pressure elements (7).

5. The power semiconductor module (1), as claimed in claim 4, wherein:
the elastic layer (10) is designed in a manner structured to form the layer regions (8a) or is of a one-piece design.

6. The power semiconductor module (1), as claimed in claim 5, wherein:
the pressure elements (7) are connected to the layer regions (8a) in a materially bonded manner.

7. The power semiconductor module (1), as claimed in claim 6, wherein:
the pressure elements (7) are connected to one another via webs (11) that are flexible in the normal direction (N) of the insulation layer (2a).

8. The power semiconductor module (1), as claimed in claim 7, wherein:
the power semiconductor module (1) has a frame element (12);
the pressure elements (7) being connected to the frame element (12) via further webs (13) that are flexible.

9. The power semiconductor module (1), as claimed in claim 8, wherein:
the frame element (12) is connected to the pressure body (6) by at least one interlocking connection (14); and
each interlocking connection (14) is a snap-action connection.

10. The power semiconductor module (1), as claimed claim 3, wherein:
at least one of the respective said pressure elements (7) has a pressure introducing portion (7b) at its end region (7a) facing the respective spring element (8); and
the pressure introducing portion (7b) having a planar surface region (7ba) facing the spring element (8) and running perpendicularly to the normal direction (N) of the insulation layer (2a) or having a concavely running surface region (7bb) facing the spring element (8).

11. The power semiconductor module (1), as claimed in claim 3, wherein:
the pressure body (6) is formed in one piece together with the spring elements (8) and with the pressure elements (7).

12. The power semiconductor module (1), as claimed in claim 11, wherein:
at least one of the spring elements (8) is formed by means of at least one slot (15) made in the pressure body (6); and
wherein at least one of the spring elements (8) has a curved profile.

13. The power semiconductor module (1), as claimed in claim 3, wherein:
the respective pressure element (7) has a foot portion (7c) running in the normal direction (N) of the insulation layer (2a) toward the substrate (2); and
the foot portion (7c) having one of a rectangular, a L-shaped, an arcuate, a circular, and a square cross section.

14. The power semiconductor module (1), as claimed in claim 3, wherein:
the power semiconductor components (3) are electrically conductively connected to the conductor tracks (2b′) of the structured metal layer (2b) by respective bonding wires (16) of the power semiconductor module (1);
the bonding wires (16) being formed from a copper alloy;
the power semiconductor components (3), contacting with the bonding wires (16), each having a metallization metal layer (17);
each respective bonding wire (16) being electrically conductively contacted with the respective metallization metal layer (17) by an ultrasonic welding connection.

15. The power semiconductor module (1), as claimed in claim 1, wherein:
the power semiconductor module (1) has a pressure generating device (19) that generates a pressure (D2) acting on the pressure body (6) in the direction of the substrate (2).

16. The power semiconductor module (1), as claimed in claim 15, wherein:
the pressure generating device (19) transmits the pressure (D2) generated by it onto the pressure body (6) via at least one spring (20); and
the spring (20) arranged between the pressure generating device (19) and the pressure body (6), of the power semiconductor module (1).

17. The power semiconductor module (1), as claimed in claim 1, wherein:
the pressure body (6) is a part of a first housing element (24) of the power semiconductor module (1).

18. The power semiconductor module (1), as claimed in claim 17, wherein:
the power semiconductor module (1) has a second housing element (25) encircling the substrate (2) and connected to the substrate (2);
the first housing element (24) connected to the second housing element (25) by an interlocking connection (26) designed as a snap-action connection (26) so that the pressure body (6), when the first housing element (24) is in a first position (P1) in relation to the second housing element (25), and does not exert any pressure (D1) onto the pressure elements (7) in the direction toward the substrate (2) via the spring elements (8);
the interlocking connection (26) are positioned so that the first housing element (24), starting from the first position (P1) of the first housing element (24), can be moved to a second position (P2) in the normal direction (N) of the insulation layer (2a) toward the substrate (2);
the pressure body (6), when the first housing element (24) is in the second position (P2) in relation to the second housing element (25) does not exert any pressure (D1) onto the pressure elements (7) in the direction toward the substrate (2) via the spring elements (8) in the first position; and
exerting a pressure (D1) onto the pressure elements (7) in the direction toward the substrate (2) via the spring elements (8), or the pressure body (6), when the pressure body (6) exerts only a slight pressure (D1) onto the pressure elements (7) in the direction toward the substrate (2) via the spring elements (8) in the first position and exerting a higher pressure (D1) than in the first position (P1) onto the pressure elements (7) in the direction toward the substrate (2) via the spring elements (8).

19. The power semiconductor module (1), as claimed in claim 15, wherein:
the pressure generating device (19) is a fastening means (19) arranged to fasten the power semiconductor module (1) on a cooling device (21).

20. The power semiconductor module (1), as claimed in claim 19, wherein:
the cooling device (21) is a base plate formed to either be a heat sink (21′) or fit to a heat sink (21′).

21. A power semiconductor device (30), comprising:
a power semiconductor module (1), according to claim 1;
further comprising:
a cooling device (21);
wherein the pressure body (6) exerts pressure onto the pressure elements (7) in the direction toward the substrate (2) via the spring elements (8), so that the substrate (2) is pressed against the cooling device (21).
